(19) United States
(12) Patent Application Publication
(10) Pub. No.: US 2005/0173812 A1
(43) Pub. Date: Aug. 11, 2005

(54) Microsystem enclosure and method of hermetic sealing

(76) Inventors: Howard Morgenstern, Lee's Summit, MO (US); David Kautz, Lenexa, KS (US); Roy J. Blazek, Overland Park, KS (US)

Correspondence Address: HOVEY WILLIAMS LLP;Suite 400, 2405 Grand Blvd., Kansas City, MO, 64108, US

(21) Appl. No.: 10/774,926

(22) Filed: Feb. 6, 2004

(51) Int. Cl. H01L 23/28

(52) U.S. Cl. 257/787

(57) ABSTRACT

A microsystem enclosure for hermetically sealing and thereby protecting a microsystem located on a substrate from the potentially damaging effects of exposure to moisture, dust, and other external environmental or operating conditions. The enclosure broadly comprises a single-piece hermetic cover structure and a single solder preform. The preform facilitates sealing the cover to the substrate in high-temperature, single-step process so as to create a hermetic cavity wherein the microsystem resides.

### FEDERALLY SPONSORED RESEARCH OR DEVELOPMENT PROGRAM

The present invention was developed with support from the U.S. government under Contract No. DE-AC04-01AL66850 with the U.S. Department of Energy. Accordingly, the U.S. government has certain rights in the present invention.

### BACKGROUND OF THE INVENTION

1. Field of the Invention

The present invention relates broadly to enclosures for hermetically sealing microsystems against potentially damaging external environments. More particularly, the present invention concerns a microsystem enclosure comprising a single-piece cover and associated single solder preform that is hermetically sealed over a microsystem in a high temperature single-step process.

2. Description of the Prior Art

Microsystems are well-known in the prior art and typically include miniature electronic or mechanical components and may take the form of, for example, microcircuits (HMCs and MCMs), semiconductor packages, microelectromechanical systems (MEMs), and optoelectronics. Due to the extremely small and otherwise delicate nature of these microsystems, it is often desirable or necessary to minimize the potentially damaging effects of exposure to moisture, dust, and other external environmental or operating conditions in order to achieve a high degree of reliability and ensure long-term operation. Referring to FIG. 1, the microsystem is located on a substrate 10, and the microsystem is hermetically sealed beneath a protective enclosure structure 12. The prior art process for achieving such a hermetic seal requires first that a metal seal ring 14 with an associated first solder preform 16 be soldered to the substrate 10. Then, a flat metal lid 18 with an associated second solder preform 20 is soldered to the seal ring 14. Thus, the seal ring 14 forms the walls of the enclosure 12 and the flat lid 18 forms the top. Solder preforms are used in order to provide consistent part-to-part dimensions that result in consistent solder volumes, thereby facilitating achieving consistency in solder assembly.

Unfortunately, this two-piece enclosure and multi-step encapsulation process increases processing time; increases risks of leaks that could expose the microsystem components to adverse environmental conditions; and reduces process yields. Risk of leakage between the hermetic cavity and the surrounding environment is increased at least in part because of the multiple solder joints and associated larger solder area whereat failures or other defects may appear. Furthermore, use of the metal seal ring and first solder preform increases the amount of area required to accommodate the two-piece enclosure, resulting in a larger microcircuit than would otherwise be necessary.

Due to the above-identified and other problems and disadvantages encountered in the prior art, a need exists for an improved microsystem enclosure.

### SUMMARY OF THE INVENTION

The present invention overcomes the above-described and other problems and disadvantages in the prior art with a microsystem enclosure and method for hermetically sealing and thereby protecting a microsystem from the potentially damaging effects of exposure to moisture, dust, and other external environmental or operating conditions to thereby achieve a high degree of reliability and ensure long-term operation. The preferred microsystem enclosure broadly comprises a single-piece hermetic cover structure and a single solder preform. The cover seals to a substrate underlying the microsystem so as to create a hermetic cavity wherein the microsystem resides. No separate seal ring and associated second solder preform is required. The solder preform facilitates hermetically sealing the cover over the microsystem in a high-temperature single-step process. No second step is required, and the result is a single, more robust solder joint that reduces risks of leakage between the hermetic cavity and the surrounding environment.

Thus, it will be appreciated that the housing of the present invention provides a number of substantial advantages over the prior art, including, for example, providing a single piece enclosure and single-step encapsulation process that decreases processing time; decreases risks of leaks that could expose the microsystem components to adverse environmental conditions; and increases process yields. Furthermore, elimination of the metal seal ring and first solder preform used in the prior art advantageously reduces the amount of area required to accommodate the single-piece enclosure, resulting in a smaller microcircuit and potentially higher level of integration than was possible in the prior art.

These and other important features of the present invention are more fully described in the section titled DETAILED DESCRIPTION OF A PREFERRED EMBODIMENT, below.

### BRIEF DESCRIPTION OF THE DRAWINGS

A preferred embodiment of the present invention is described in detail below with reference to the attached drawing figures, wherein:

FIG. 1 is an exploded isometric view of a prior art microsystem enclosure;

FIG. 2 is an exploded isometric view of a preferred embodiment of the microsystem enclosure of the present invention; and

FIG. 3 is a fragmentary isometric view of the microsystem enclosure of FIG. 2 following single-step hermetic sealing.

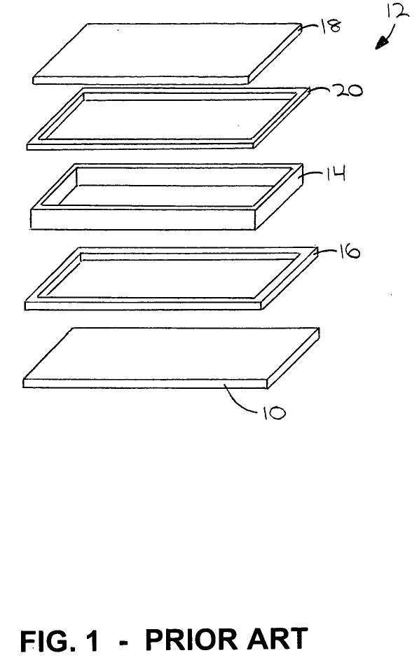

### DETAILED DESCRIPTION OF A PREFERRED EMBODIMENT

With reference to the figures, a microsystem enclosure 24 and hermetic sealing method is described, shown, and otherwise disclosed herein in accordance with a preferred embodiment of the present invention. Broadly, the enclosure 24 is adapted and operable to hermetically seal and thereby protect a microsystem located on a substrate 26 from the potentially damaging effects of exposure to moisture, dust, and other external environmental or operating conditions and thereby achieve a high degree of reliability and ensure long-term operation.

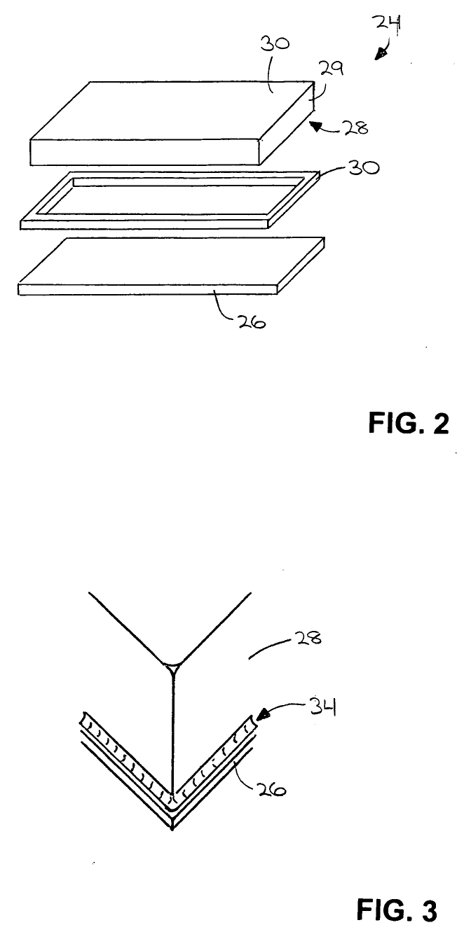

Referring particularly to FIG. 2, a preferred embodiment of the microsystem enclosure 24 broadly comprises a single-piece hermetic cover structure 28 and a single solder preform 30. The cover 28 seals to the substrate 26 underlying the microsystem to create a hermetic cavity wherein the microsystem resides. The cover 28 is a single-piece structure having walls 29 and a top 30. The cover 28 is preferably nickel and gold plated, having a burr-free, ground-flat finish. The plating is preferably a minimum of approximately 0.000075 inches of gold over a minimum of approximately 0.000050 inches of nickle. However, these characteristics and others, such as, for example, the size and shape of the cover, may vary depending on such factors as the size and nature of the microsystem being sealed, and the specific circumstances of the application.

The solder preform 32 facilitates hermetically sealing the cover 28 to the substrate 26 so as to cover the microsystem. The solder preform 32 provides consistent part-to-part dimensions that result in consistent solder volumes and ensure consistent solder assembly. Preferably, the preform 32 has a thickness of approximately 0.003 inches; a size that is maintained edge-to-edge with the cover 28; and a composition of approximately 80% gold and 20% tin. The preform 32 is preferably attached to the cover 28 in a manner similar to a “combo”. The braze pad is preferably approximately 60 mils wide, with the cover 28 centered thereupon. However, these characteristics and others may vary depending on desired performance, the size and nature of the microsystem and the cover, and the specific circumstances of the application.

In exemplary use and operation, given the microsystem, which might include, for example, a low-temperature cofired ceramic (“LTCC”) network containing active components, the enclosure 24 is hermetically sealed to the substrate 26 in a high-temperature single-step process that is otherwise substantially conventional. The result, with its single, robust solder joint 34, is shown in FIG. 3. This is in stark contrast to the prior art encapsulation technique for achieving a hermetic seal, which involves at least two processing steps, as mentioned above, including first soldering the metal seal ring 14 with the associated first solder preform 16 to the substrate 10, and then soldering a metal lid 18 with its associated second solder preform 20 to the seal ring 14.

From the preceding description, it will be appreciated that the enclosure of the present invention provides a number of substantial advantages over the prior art, including, for example, providing a single-piece enclosure and single-step encapsulation process that decreases processing time; decreases risks of leaks that could expose the microsystem components to adverse environmental conditions; and increases process yields. Risk of leakage between the hermetic cavity and the surrounding environment is decreased at least in part by a single, more robust solder joint. Furthermore, elimination of the metal seal ring and first solder preform used in the prior art advantageously reduces the amount of area required to accommodate the single-piece enclosure, resulting in a smaller microcircuit and potentially higher level of integration than was possible in the prior art.

Potential applications for the present invention include any aerospace, automotive, computer, medical, or consumer electronics where protection of miniature electronic or mechanical components from environmental conditions is required or desired.

Although the invention has been described with reference to the preferred embodiments illustrated in the attached drawings, it is noted that equivalents may be employed and substitutions made herein without departing from the scope of the invention as recited in the claims. It will be appreciated, for example, that the cover and preform may take or have substantially any desired or required shape or composition in order to conform to and accommodate a particular application.

Having thus described the preferred embodiment of the invention,

1. An enclosure for hermetically sealing a microsystem, wherein the microsystem is located on a substrate, the enclosure comprising:
a single-piece cover having walls and a top; and
a solder preform interposed between the single-piece cover and the substrate in order to facilitate creating a hermetically sealed cavity defined by the single-piece cover and the substrate for enclosing the microsystem.

2. The enclosure as set forth in claim 1, wherein the single-piece cover includes a layer of gold-plating over a layer of nickel-plating.

3. The enclosure as set forth in claim 2, wherein the layer of gold-plating is approximately at least 0.000075 inches in thickness, and the layer of nickel-plating is approximately at least 0.000050 inches in thickness.

4. The enclosure as set forth in claim 1, wherein the solder preform has a thickness of approximately 0.003 inches.

5. The enclosure as set forth in claim 1, wherein the solder preform has a composition of approximately 80% gold and 20% tin.

6. An enclosure for hermetically sealing a microsystem, the enclosure comprising:
a substrate whereupon is located the microsystem;
a single-piece cover having walls and a top; and
a single solder preform interposed directly between the single-piece cover and the substrate in order to facilitate creating a hermetically sealed cavity defined by the single-piece cover and the substrate for enclosing the microsystem.

7. The enclosure as set forth in claim 6, wherein the single-piece cover includes a layer of gold-plating over a layer of nickel-plating.

8. The enclosure as set forth in claim 7, wherein the layer of gold-plating is approximately at least 0.000075 inches in thickness, and the layer of nickel-plating is approximately at least 0.000050 inches in thickness.

9. The enclosure as set forth in claim 6, wherein the solder preform has a thickness of approximately 0.003 inches.

10. The enclosure as set forth in claim 6, wherein the solder preform has a composition of approximately 80% gold and 20% tin.

11. An enclosure for hermetically sealing a microsystem, the enclosure comprising:
a substrate whereupon is located the microsystem;
a single-piece cover having walls and a top, wherein the single-piece cover includes a layer of gold-plating that is approximately 0.000075 inches in thickness over a layer of nickel-plating that is approximately 0.000050 inches in thickness; and
a single solder preform having a thickness of approximately 0.003 inches and a composition of approximately 80% gold and 20% tin, wherein the solder preform is interposed directly between the single-piece cover and the substrate in order to facilitate creating a hermetically sealed cavity defined by the single-piece cover and the substrate for enclosing the microsystem.

12. (canceled)

13. (canceled)

14. (canceled)

15. (canceled)

16. (canceled)

17. (canceled)

18. (canceled)

19. (canceled)

20. (canceled)

21. (canceled)

22. (canceled)
